(19) United States
(12) Patent Application Publication
(10) Pub. No.: US 2014/0174805 A1
(43) Pub. Date: Jun. 26, 2014

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventor: Takayuki Haze, Suwon (KR)

(73) Assignee: SAMSUNG ELECTRO-MECHANICS CO., LTD., Suwon (KR)

(21) Appl. No.: 13/802,553

(22) Filed: Mar. 13, 2013

(30) Foreign Application Priority Data
Dec. 24, 2012 (KR) 10-2012-0152426

(51) Int. Cl. H05K 3/34

(52) U.S. Cl. CPC H05K 3/34
USPC 174/260; 174/250; 29/887; 29/829; 29/840; 29/832

(57) ABSTRACT

Disclosed herein is a printed circuit board, including: a base substrate; a non-photosensitive insulating layer formed on the base substrate; a circuit pattern formed on the base substrate and having an upper portion protruded from an upper portion of the non-photosensitive insulating layer; and a dam made of a photosensitive material and formed on the upper portion of the non-photosensitive insulating layer of an outer side of the base substrate.

### CROSS REFERENCE TO RELATED APPLICATION

This application claims the benefit of Korean Patent Application No. 10-2012-0152426, filed on Dec. 24, 2012, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

In relation to a printed circuit board having an underfill solution leakage preventing solder resist formed thereon and a method of manufacturing the same according to a prior art, a primary solder resist process forming an external layer circuit, applying a photosensitive solder resist thereto to perform exposure and development, and then exposing a circuit pattern forming a solder bump for mounting a semiconductor has progressed. In addition, in a secondary solder resist process, the photosensitive solder resist is applied one more thereto to perform the exposure and development and then exposing a region on which the semiconductor is mounted to form a cavity structure is conducted.

In the method of manufacturing the printed circuit board having the underfill solution leakage preventing solder resist formed thereon according to the prior art as described above, in order to secure accuracy of a fine position matching for exposing the circuit pattern forming the solder bump, an expensive exposure device is needed as well as risk decreasing yield due to position matching defect is present.

### PRIOR ART DOCUMENT

### Patent Document

(Patent Document 1) Korean Patent No. 1022942

### SUMMARY OF THE INVENTION

The present invention has been made in an effort to provide a printed circuit board having improved reliability and process simplicity.

Further, the present invention has been made in an effort to provide a method of manufacturing the printed circuit board having improved reliability and process simplicity.

According to a preferred embodiment of the present invention, there is provided a printed circuit board, including: a base substrate; a non-photosensitive insulating layer formed on the base substrate; a circuit pattern formed on the base substrate and having an upper portion protruded from an upper portion of the non-photosensitive insulating layer; and a dam made of a photosensitive material and formed on the upper portion of the non-photosensitive insulating layer of an outer side of the base substrate.

The printed circuit board may further include a bump formed on the circuit pattern.

A first electronic element may be mounted on the bump.

A second electronic element may be embedded in the base substrate.

The circuit pattern may be electrically connected to an electrode pad of the second electronic element.

The dam may have an upper surface positioned at a height higher than that of a lower substrate in order to cover the circuit pattern; and exposing an upper portion of the circuit pattern by partially removing the photosensitive insulating layer.

In the exposing of the upper portion of the circuit pattern, the photosensitive insulating layer may be partially removed, such that a dam may be formed at an outer side of the base substrate.

The method may further include forming a bump on the circuit pattern, after the exposing of the upper portion of the circuit pattern.

The method may further include mounting a first electronic element on the bump, after the forming of the bump.

A second electronic element may be embedded in the base substrate.

The circuit pattern may be electrically connected to an electrode pad of the second electronic element.

In the laminating of the non-photosensitive insulating layer and the photosensitive material, the non-photosensitive insulating layer may be formed so as to expose the upper portion of the circuit pattern.

In the forming of the dam, the dam may have an upper surface positioned at a height higher than that of a lower surface of the first electronic element.

### BRIEF DESCRIPTION OF THE DRAWINGS

FIG. 1 is a cross-sectional view showing a printed circuit board according to a preferred embodiment of the present invention;

FIG. 2 is a cross-sectional view showing a printed circuit board according to another preferred embodiment of the present invention;

FIGS. 3 to 8 are exemplary views showing a method of manufacturing a printed circuit board according to the preferred embodiment of the present invention; and

FIG. 9 is a cross-sectional view showing the printed circuit board according to the preferred embodiment of the present invention.

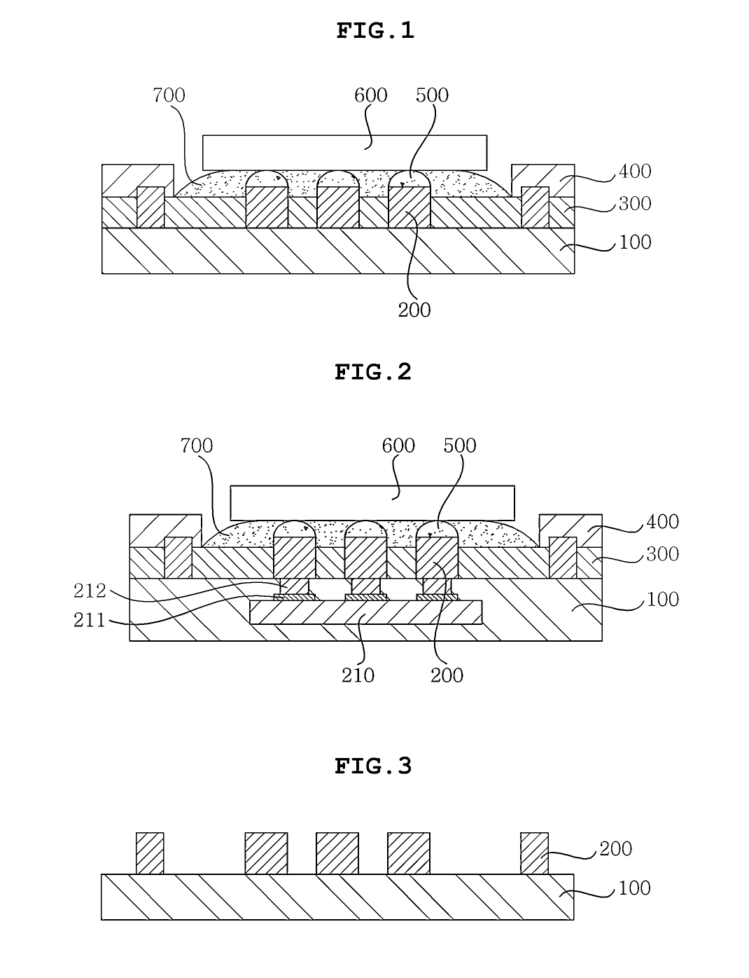

FIG. 1 is a cross-sectional view showing a printed circuit board according to a preferred embodiment of the present invention;

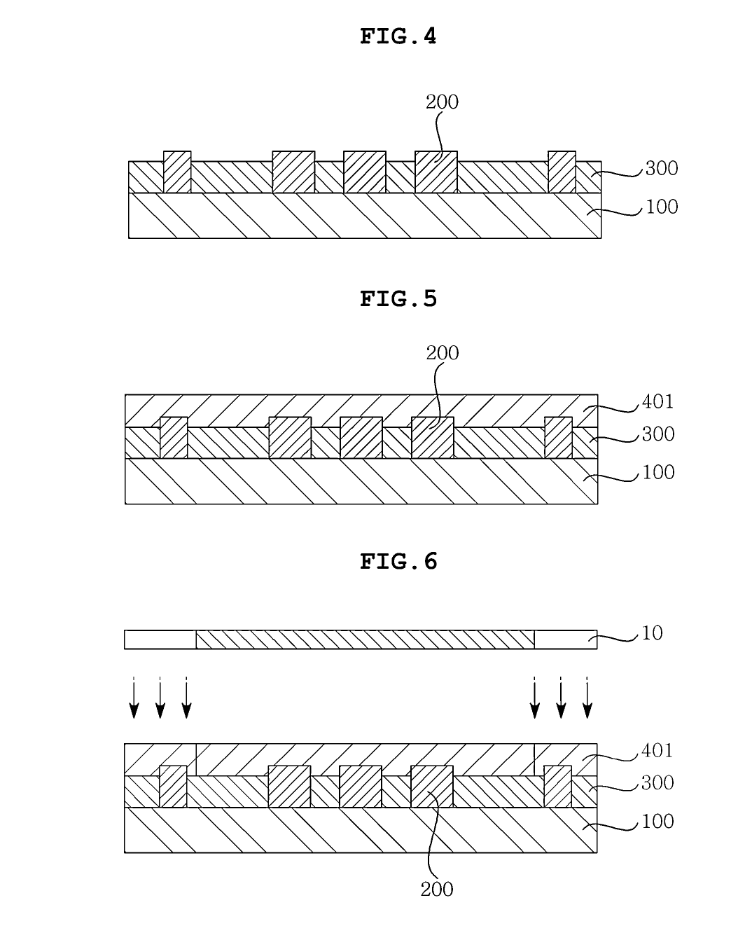

FIG. 2 is a cross-sectional view showing a printed circuit board according to another preferred embodiment of the present invention;

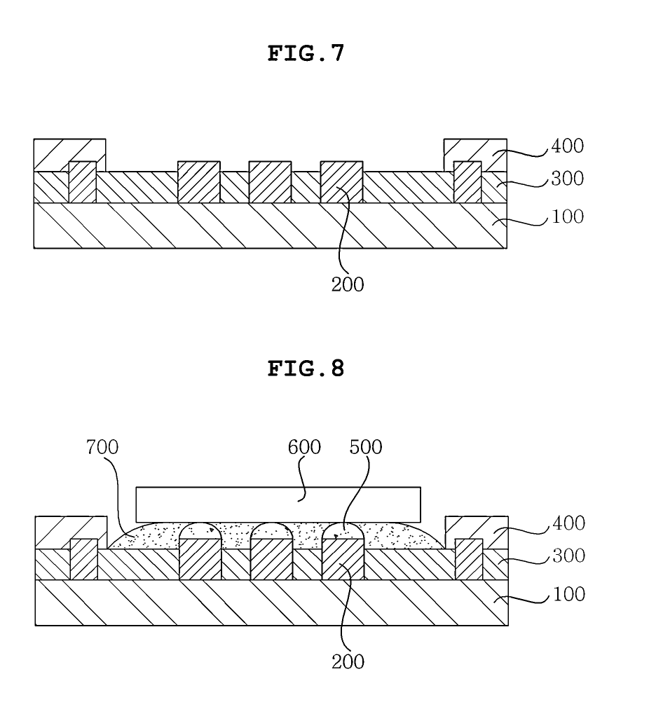

FIGS. 3 to 8 are exemplary views showing a method of manufacturing a printed circuit board according to the preferred embodiment of the present invention; and

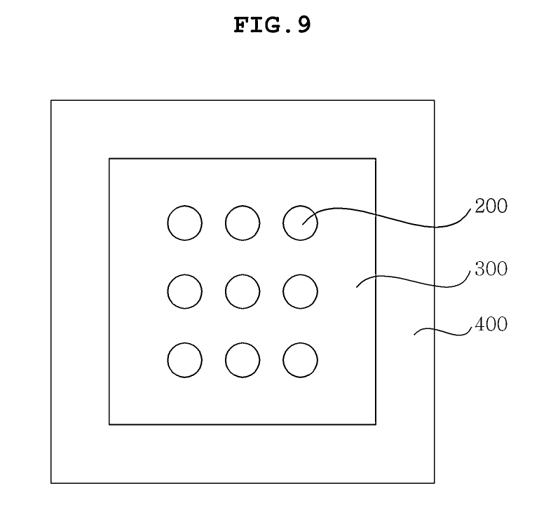

FIG. 9 is a cross-sectional view showing the printed circuit board according to the preferred embodiment of the present invention.

### DESCRIPTION OF THE PREFERRED EMBODIMENTS

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the attached drawings.

FIG. 1 is a cross-sectional view showing a printed circuit board according to a preferred embodiment of the present invention.

Referring to FIG. 1, a printed circuit board according to a preferred embodiment of the present invention may include a base substrate 100, a non-photosensitive insulating layer 300, and a dam 400.

The base substrate 100 may be provided with a circuit pattern 200. The base substrate 100 may generally be a complex polymer resin used as an interlayer insulating material. For example, a prepreg is employed as the base substrate 100, thereby making it possible to manufacture the printed circuit board thinner. Alternatively, an ajinomoto build up film (ABF) is employed as the base substrate 100, thereby making it possible to easily implement a fine circuit. In addition to this, the base substrate 100 may use an epoxy based resin such as FR-4, bismaleimide triazine (BT), and the like, but is not particularly limited thereto. Alternatively, a copper clad laminate (CCL) may be used as the base substrate 100. Meanwhile, although FIG. 1 shows a case in which the base substrate 100 is configured of a single layer, the present invention is not limited thereto. That is, the base substrate 100 may be an insulating layer and a circuit layer having a multi-layer or a single layer, and a build-up layer configured of a via.

In the preferred embodiment of the present invention, the base substrate 100 may include the circuit pattern 200. The circuit pattern 200 may be a configuration part electrically connected to the outside first electronic element 600.

The non-photosensitive insulating layer 300 may be laminated on the base substrate 100. The non-photosensitive insulating layer 300 may be formed at a height lower than that of the circuit pattern 200. That is, in the case in which the non-photosensitive insulating layer 300 is laminated on the base substrate 100, an upper portion of the circuit pattern 200 may be protruded from an upper surface of the non-photosensitive insulating layer 300. The non-photosensitive insulating layer 300 may be made of a thermosetting epoxy resin. Here, the thermosetting epoxy resin may contain an inorganic filler.

The dam 400 may protrude outwardly from an upper portion of the base substrate 100. In addition, the dam 400 may be made of a photosensitive material. The photosensitive material may be made of an alkali development type epoxy-acrylate resin or a solvent development type epoxy-acrylate resin. Here, the alkali development type epoxy-acrylate resin or the solvent development type epoxy-acrylate resin may contain the inorganic filler.

The dam 400 may be formed by laminating the photosensitive material on the non-photosensitive insulating layer 300 and then patterning the photosensitive material through exposure and development processes. In this configuration, the dam 400 may be formed so as to expose the upper surface of the circuit pattern 200 to the outside. Here, the circuit pattern 200 exposed by the dam 400 may be a configuration part electrically connected to the first electronic element 600. In addition, the dam 400 may have an upper surface formed at position higher than that of a lower surface of the first electronic element 600 which is later mounted. This configuration is to prevent an underfill solution injected between the first electronic element 600 and the circuit pattern 200 after mounting the first electronic element 600 from being leaked to the outside of the dam 400. Here, the first electronic element 600 may be an element such as a semiconductor chip and the like mounted on the printed circuit board. The first electronic element 600 is mounted over the circuit pattern 200 and may be bonded and electrically connected to the circuit pattern 200 by a bump 500.

The dam 400 may be formed by laminating a photosensitive material on the non-photosensitive insulating layer 300 and then exposing and developing the photosensitive material to leave only an outer side of the photosensitive material.

FIG. 2 is a cross-sectional view showing a printed circuit board according to another preferred embodiment of the present invention.

Referring to FIG. 2, a printed circuit board according to another preferred embodiment of the present invention may include a base substrate 100, a non-photosensitive insulating layer 300, and a dam 400.

The base substrate 100 may be provided with a circuit pattern 200. The base substrate 100 may generally be a complex polymer resin used as an interlayer insulating material. For example, a prepreg is employed as the base substrate 100, thereby making it possible to manufacture the printed circuit board thinner. Alternatively, an ajinomoto build up film (ABF) is employed as the base substrate 100, thereby making it possible to easily implement a fine circuit. In addition to this, the base substrate 100 may use an epoxy based resin such as FR-4, bismaleimide triazine (BT), and the like, but is not particularly limited thereto. Alternatively, a copper clad laminate (CCL) may be used as the base substrate 100. Meanwhile, although FIG. 1 shows a case in which the base substrate 100 is configured of a single layer, the present invention is not limited thereto. That is, the base substrate 100 may be an insulating layer and a circuit layer having a multi-layer or a single layer, and a build-up layer configured of a via.

In the preferred embodiment of the present invention, the base substrate 100 may include the circuit pattern 200. The circuit pattern 200 may be a configuration part electrically connected to the outside first electronic element 600. In addition, the base substrate 100 may have a second electronic element 210 formed therein. As described above, in the case in which the second electronic element 210 is embedded in the base substrate 100, the circuit pattern 200 may be electrically connected to an electrode pad 211 of the second electronic element 210. The electrode pad 211 of the second electronic element 210 and the circuit pattern 200 may be electrically connected to each other through a via 212. The second electronic element 210 may generally be a semiconductor chip and the like as an element embedded in the printed circuit board.

The non-photosensitive insulating layer 300 may be laminated on the base substrate 100. The non-photosensitive insulating layer 300 may be formed at a height lower than that of the circuit pattern 200. That is, in the case in which the non-photosensitive insulating layer 300 is laminated on the base substrate 100, an upper portion of the circuit pattern 200 may be protruded from an upper surface of the non-photosensitive insulating layer 300. The non-photosensitive insulating layer 300 may be made of a thermosetting epoxy resin. Here, the thermosetting epoxy resin may contain an inorganic filler.

The dam 400 may protrude outwardly from an upper portion of the base substrate 100. In addition, the dam 400 may be made of a photosensitive material. The photosensitive material may be made of an alkali development type epoxy-acrylate resin or a solvent development type epoxy-acrylate resin. Here, the alkali development type epoxy-acrylate resin or the solvent development type epoxy-acrylate resin may contain the inorganic filler.

The dam 400 may be formed by laminating it on the non-photosensitive insulating layer 300 and then patterning it through the exposure and development processes. In this configuration, the dam 400 may be formed so as to expose the upper surface of the circuit pattern 200 to the outside. Here, the circuit pattern 200 without the dam 400 formed thereon and exposed to the outside may be a configuration part electrically connected to the first electronic element 600. In addition, the dam 400 may have an upper surface formed at position higher than that of a lower surface of the first electronic element 600 which is later mounted. This configuration is to prevent an underfill solution injected between the first electronic element 600 and the circuit pattern 200 after mounting the first electronic element 600 from being leaked to the outside of the dam 400. Here, the first electronic element 600 may be an element such as the semiconductor chip and the like mounted on the printed circuit board. The first electronic element 600 is mounted over the circuit pattern 200 and may be bonded and electrically connected to the circuit pattern 200 by a bump 500.

The dam 400 may be formed by laminating a photosensitive material on the non-photosensitive insulating layer 300 and then exposing and developing the photosensitive material to leave only an outer side of the photosensitive material.

FIGS. 3 to 8 are exemplary views showing a method of manufacturing a printed circuit board according to the preferred embodiment of the present invention.

Referring to FIG. 3, the base substrate 100 having the circuit pattern 200 formed thereon may be prepared. The base substrate 100 may generally be a complex polymer resin used as an interlayer insulating material. For example, a prepreg is employed as the base substrate 100, thereby making it possible to manufacture the printed circuit board thinner. Alternatively, an ajinomoto build up film (ABF) is employed as the base substrate 100, thereby making it possible to easily implement a fine circuit. In addition to this, the base substrate 100 may use an epoxy based resin such as FR-4, bismaleimide triazine (BT), and the like, but is not particularly limited thereto. Alternatively, a copper clad laminate (CCL) may be used as the base substrate 100. Meanwhile, although FIG. 1 shows a case in which the base substrate 100 is configured of a single layer, the present invention is not limited thereto. That is, the base substrate 100 may be an insulating layer and a circuit layer having a multi-layer or a single layer, and a build-up layer configured of a via.

In the preferred embodiment of the present invention, the base substrate 100 may include the circuit pattern 200. The circuit pattern 200 may be a configuration part electrically connected to the outside first electronic element 600. In addition, the base substrate 100 may have a second electronic element (not shown) formed therein. As described above, in the case in which the second electronic element (not shown) is embedded in the base substrate 100, the circuit pattern 200 may be electrically connected to an electrode pad of the second electronic element (not shown).

Referring to FIG. 4, the non-photosensitive insulating layer 300 may be formed on the base substrate 100. According to the preferred embodiment of the present invention, the non-photosensitive insulating layer 300 may be formed at a height lower than that of the circuit pattern 200. That is, the non-photosensitive insulating layer 300 may be formed so that the upper portion of the circuit pattern 200 is exposed to the outside. The non-photosensitive insulating layer 300 may be made of a thermosetting epoxy resin. Here, the thermosetting epoxy resin may contain an inorganic filler.

Referring to FIG. 5, a photosensitive insulating layer 401 may be formed on the no-photosensitive insulating layer 300. The photosensitive insulating layer 401 may entirely cover the upper portion of the circuit pattern 200 protruded from the non-photosensitive insulating layer 300. The photosensitive insulating layer 401 may be made of an alkali development type epoxy-acrylate resin or a solvent development type epoxy-acrylate resin. Here, the alkali development type epoxy-acrylate resin or the solvent development type epoxy-acrylate resin may contain the inorganic filler.

Although the preferred embodiment of the present invention shows a case in which the non-photosensitive insulating layer 300 and the photosensitive insulating layer 401 are sequentially laminated on the base substrate 100, the present invention is not limited thereto. For example, the non-photosensitive insulating layer 300 and the photosensitive insulating layer 401 may be formed of a single film having a two-layer structure. That is, the film having the two-layer structure formed of the non-photosensitive insulating layer 300 and the photosensitive insulating layer 401 may be laminated on the base substrate 100 at the same time.

Referring to FIG. 6, the exposure may be performed for the photosensitive insulating layer 401. First, an exposure mask 10 may be positioned over the photosensitive insulating layer 401. The exposure mask 10 may be formed so that a position at which the dam 400 is formed is closed and a region on which the first electronic element (600 in FIG. 8) is mounted is opened. After the above-mentioned exposure mask 10 is positioned, the exposure may be performed. Although the preferred embodiment of the present invention describes a case in which the exposure mask 10 is formed so that the region on which the first electronic element (600 in FIG. 8) is mounted is opened, the present invention is not limited thereto. For example, in the case in which the photo-sensitive insulating layer 401 is a negative type, the region on which the first electronic element (600 in FIG. 8) is mounted is closed. That is, the exposure mask 10 may change form according to the type of the photosensitive insulating layer 401.

Referring to FIG. 7, the development may be performed for the photosensitive insulating layer 401 in which the exposure is performed. By performing the development, the region of the photosensitive insulating layer 401 on which the first electronic element (600 in FIG. 8) is mounted is removed, thereby making it possible to form the dam 400. In the region in which the photosensitive insulating layer 401 is removed, the upper portion of the circuit pattern 200 may be exposed to the outside. In addition, the dam 400 may protrude outwardly from an upper portion of the non-photosensitive insulating layer 300. That is, the dam 400 may protrude outwardly from the upper portion of the base substrate 100. In this configuration, the dam 400 may have an upper surface formed at position higher than that of a lower surface of the first electronic element (600 in FIG. 8) which is later mounted.

Referring to FIG. 8, the first electronic element 600 may be mounted over the base substrate 100. First, a bump 500 may be formed on the circuit pattern 200. The bump 500 may be formed to bond and electrically connect between the circuit pattern 200 and the first electronic element 600. The bump 500 may be formed by applying a solder paste on the circuit pattern 200. Although FIG. 7 describes the bump 500 formed using the solder, the present invention is not limited thereto. The configuration part for bonding the first electronic element 600 over the circuit pattern 200 may be formed by applying the bump 500 formed using the solder as well as a known technology such as a metal post and the like. This may be designed and changed by those skilled in the art.

After forming the bump 500 as described above, the first electronic element 600 may be mounted on the bump 500. Here, the first electronic element 600 may be a general element such as the semiconductor chip and the like generally mounted on the printed circuit board.

In addition, after mounting the first electronic element 600, an underfill solution 70 may be injected into a space between the first electronic element 600 and the upper portion of the base substrate 100. In this case, since the dam 400 may have the upper surface formed at position higher than that of the lower surface of the first electronic element 600, it is possible to prevent the underfill solution 700 from being leaked to the outside of the dam 400.

FIG. 9 is a cross-sectional view showing the printed circuit board according to the preferred embodiment of the present invention.

As shown in FIG. 9, as viewed the printed circuit board from above, it may be appreciated that a central portion of the printed circuit board is provided with a plurality of circuit patterns 200 disposed at a predetermined interval in a vertical and horizontal direction and the non-photosensitive insulating layer 300 encloses the plurality of the circuit patterns 200. Although FIG. 9 shows a case in which the number of the circuit patterns 200 is nine, it is only an example, and the number of the circuit patterns 200 is not limited thereto.

In addition, it may be appreciated that the dam 400 made of a photosensitive material encloses a circumference of the non-photosensitive insulating layer 300. In this configuration, although not identified in FIG. 9, referring to FIG. 1, it may be appreciated that the height is higher in a sequence of the dam 400, the circuit pattern 200, and the non-photosensitive insulating layer 300. Here, since the dam 400 has the highest height, it may be appreciated that the leakage of the underfill solution to the outside may be prevented.

In relation to the printed circuit board having the underfill solution leakage preventing dam formed thereon and the method of manufacturing the same according to the preferred embodiment of the present invention as described above, according to the prior art, since the exposure and development should be performed two times in order to form the underfill solution leakage preventing dam, the manufacturing process is complicated as well as manufacturing costs are increased. However, since the preferred embodiment of the present invention may form the underfill solution leakage preventing dam by performing the exposure and development one time for the two-layer solder resist made of the non-photosensitive insulating layer and the photosensitive material, the manufacturing process is simplified as well as the manufacturing cost is decreased.

The printed circuit board according to the preferred embodiment of the present invention may improve reliability and process simplicity.

The method of manufacturing the printed circuit board according to the preferred embodiment of the present invention may improve reliability and process simplicity.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate;
a non-photosensitive insulating layer formed on the base substrate;
a circuit pattern formed on the base substrate and having an upper portion protruded from an upper portion of the non-photosensitive insulating layer; and
a dam made of a photosensitive material and formed on the upper portion of the non-photosensitive insulating layer of an outer side of the base substrate.

2. The printed circuit board as set forth in claim 1, further comprising a bump formed on the circuit pattern.

3. The printed circuit board as set forth in claim 2, wherein a first electronic element is mounted on the bump.

4. The printed circuit board as set forth in claim 1, wherein a second electronic element is embedded in the base substrate.

5. The printed circuit board as set forth in claim 4, wherein the circuit pattern is electrically connected to an electrode pad of the second electronic element.

6. The printed circuit board as set forth in claim 3, wherein the dam has an upper surface positioned at a height higher than that of a lower surface of the first electronic element.

7. A method of manufacturing a printed circuit board, the method comprising:
preparing a base substrate having a circuit pattern formed thereon;
sequentially laminating a non-photosensitive insulating layer and a photosensitive insulating layer over the base substrate in order to cover the circuit pattern; and
exposing an upper portion of the circuit pattern by partially removing the photosensitive insulating layer.

8. The method as set forth in claim 7, wherein in the exposing of the upper portion of the circuit pattern, the photosensitive insulating layer is partially removed, such that a dam is formed at an outer side of the base substrate.

9. The method as set forth in claim 7, further comprising forming a bump on the circuit pattern, after the exposing of the upper portion of the circuit pattern.

10. The method as set forth in claim 9, further comprising mounting a first electronic element on the bump, after the forming of the bump.

11. The method as set forth in claim 7, wherein a second electronic element is embedded in the base substrate.

12. The method as set forth in claim 11, wherein the circuit pattern is electrically connected to an electrode pad of the second electronic element.

13. The method as set forth in claim 7, wherein in the laminating of the non-photosensitive insulating layer and the photosensitive material, the non-photosensitive insulating layer is formed so as to expose the upper portion of the circuit pattern.

14. The method as set forth in claim 10, wherein in the forming of the dam, the dam has an upper surface positioned at a height higher than that of a lower surface of the first electronic element.
